(19) United States
(12) Patent Application Publication
(10) Pub. No.: US 2009/0233020 A1
(43) Pub. Date: Sep. 17, 2009

(54) GLAZING ASSEMBLY AND METHOD

(75) Inventors: Roger D. O'Shaughnessy, Wayzata, MN (US); Robert C. Grommesh, St. Louis Park, MN (US); Richard A. Palmer, Delano, MN (US)

Correspondence Address: INTELLECTUAL PROPERTY GROUP;FREDRIKSON & BYRON, P.A., 200 SOUTH SIXTH STREET, SUITE 4000, MINNEAPOLIS, MN, 55402, US

(73) Assignee: CARDINAL LG COMPANY, Eden Prairie, MN (US)

(21) Appl. No.: 12/233,313

(22) Filed: Sep. 18, 2008

Related U.S. Application Data
(60) Provisional application No. 60/973,823, filed on Sep. 20, 2007.

(51) Int. Cl. E06B 3/66; B32B 37/14

(52) U.S. Cl. 428/34; 156/103

(57) ABSTRACT

A glazing assembly includes a functional coating extending over, and being adhered to a central region of an inner major surface of a first substrate, which opposes a second substrate, whose inner surface includes a central region facing the functional coating; a spacer member, which is directly adhered to aligned peripheries of the inner major surfaces, joins the substrates, such that an airspace is enclosed between the central regions thereof. The spacer member may be pre-formed from a material having properties that result in a relatively low moisture vapor transmission rate therethrough, and may have a pre-formed footprint that matches a shape of the periphery of each of the substrates. A silane primer may be applied to the peripheries of the substrates to improve hydrolytic stability of the adhesion between the substrates and the spacer member.

### PRIORITY CLAIM

The present application claims priority to U.S. provisional application Ser. No. 60/973,823, entitled GLAZING ASSEMBLY AND METHOD, which was filed on Sep. 20, 2007 and is hereby incorporated herein, by reference, in its entirety.

### TECHNICAL FIELD

The present invention pertains to glazing assemblies, and the like, and more particularly to these assemblies that include at least two substrates, which are spaced apart from one another on either side of an airspace, and a functional coating, borne by at least one of the substrates, within the airspace.

### BACKGROUND

Insulating glass (IG) units are glazing assemblies that typically include at least a pair of panels, or substrates, joined together such that a major surface of one of the substrates faces a major surface of the other of the substrates, and an airspace is enclosed between the two substrates. At least one of the substrates is transparent, or light transmitting, and may bear a functional coating, for example, a low emissivity coating or a photovoltaic coating, on the major surface that faces the major surface of the other substrate. Those skilled in the art appreciate that the design of this type of assembly should prevent the ingress of excess moisture into the airspace, thereby protecting the integrity of the functional coating. Although various designs have been proposed to address this need, there is still a need for new and improved IG unit-type glazing assembly designs, as well as related, cost-effective, methods of manufacture.

### BRIEF SUMMARY

Glazing assemblies, according to embodiments of the present invention, include a functional coating, for example, a photovoltaic or a low emissivity coating, extending over and being adhered to a central region of an inner major surface of a first substrate, which first substrate opposes a second substrate whose inner surface includes a central region facing the functional coating; the first and second substrates are joined together by a spacer member, which is directly adhered to aligned peripheries of the inner major surfaces of the first and second substrates, such that an airspace is enclosed between the central regions of the first and second substrates. The spacer member is preferably formed from a material having properties that result in a moisture vapor transmission rate therethrough of no greater than approximately 20 g mm/m²/day, in an environment characterized by a relative humidity of approximately 100% and a temperature of approximately 38° C., and as measured per ASTM F 1249.

According to some embodiments, the spacer member is pre-formed, for example, via injection molding, to have a footprint that matches a shape of the periphery of each of the first and second substrates, so that, according to preferred methods of the present invention, the spacer member may simply be placed, or sandwiched, between the peripheries of the first and second substrates, and then adhered directly thereto, for example, by, first, heating the first and second substrates and, then, pressing the substrates toward one another. According to some alternate embodiments, the spacer member includes pre-formed strips that come together at a corner of each periphery in one of: a miter joint, an overlap joint and an interlocking joint. According to some preferred embodiments, the material from which the spacer member is formed is an ethylene methacrylic acid copolymer, and a silane primer is applied to the periphery of each of the first and second substrates in order to enhance the adhesion of the spacer member thereto.

Some embodiments of the present invention further include a support member that is disposed between the central regions of the first and second substrates and, preferably, has a thickness to span the airspace therebetween. In those embodiments, which include an opening formed through the central region of second substrate, the support member may surround at least a portion of a perimeter of the opening. The opening may be used for routing a lead wire out from the airspace, for example, in those embodiments in which the functional coating is a photovoltaic coating.

### BRIEF DESCRIPTION OF THE DRAWINGS

The following drawings are illustrative of particular embodiments of the present invention and therefore do not limit the scope of the invention. The drawings are not to scale (unless so stated) and are intended for use in conjunction with the explanations in the following detailed description. Embodiments of the present invention will hereinafter be described in conjunction with the appended drawings, wherein like numerals denote like elements.

FIG. 1 is a perspective view of a glazing assembly, according to some embodiments of the present invention.

FIG. 2 is a schematic plan view of either of the substrates of the assembly shown in FIG. 1.

FIG. 3A is a perspective view of a portion of the assembly shown in FIG. 1, according to some embodiments of the present invention.

FIGS. 3B-E are plan views of portions of the assembly shown in FIG. 1, according to some alternate embodiments.

FIGS. 4-6 are section views through line A-A of FIG. 1, according to various embodiments of the present invention.

FIG. 7A is a chart presenting a first set of adhesion test results.

FIG. 7B is a chart presenting a second set of adhesion test results.

FIG. 8A is a cross-section of a portion of a coated substrate of any of the assemblies shown in FIGS. 4-6.

FIG. 8B is a perspective view of a portion of any of the assemblies shown in FIGS. 4-6, according to some further embodiments.

FIGS. 9A-B are perspective views of a portion of a glazing assembly, according to some alternate embodiments of the present invention.

FIGS. 10A-C are perspective views of a portion of a glazing assembly, according to yet further embodiments of the present invention.

FIG. 11 is a schematic describing a portion of a production line, on which some method or assembly steps of the present invention may be carried out.

### DETAILED DESCRIPTION

The following detailed description is exemplary in nature and is not intended to limit the scope, applicability, or configuration of the invention in any way. Rather, the following description provides practical illustrations for implementing exemplary embodiments of the present invention.

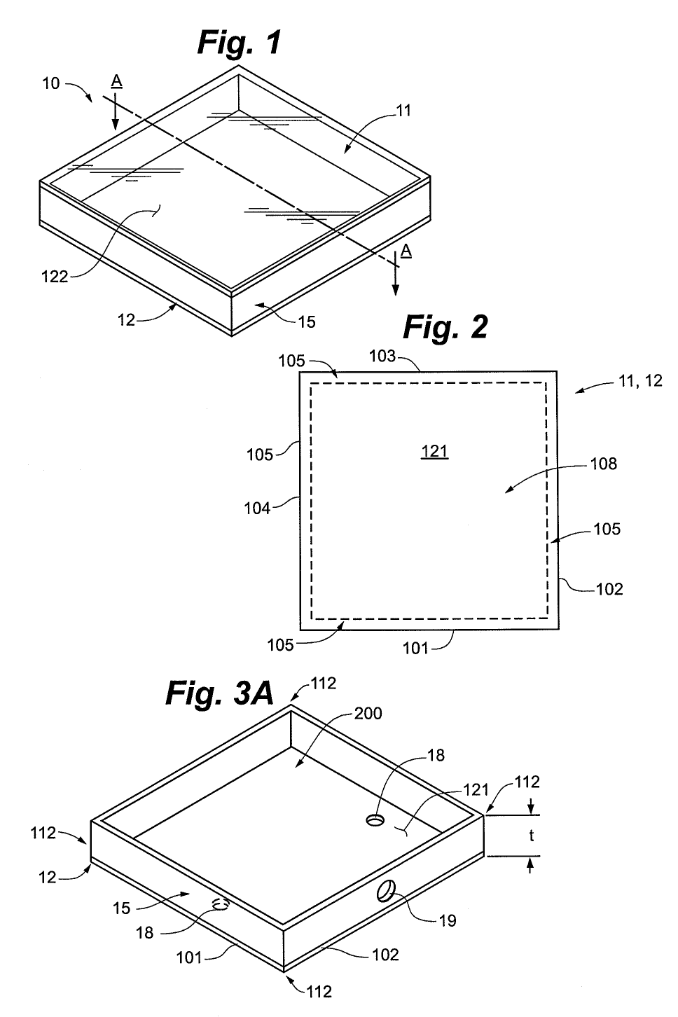

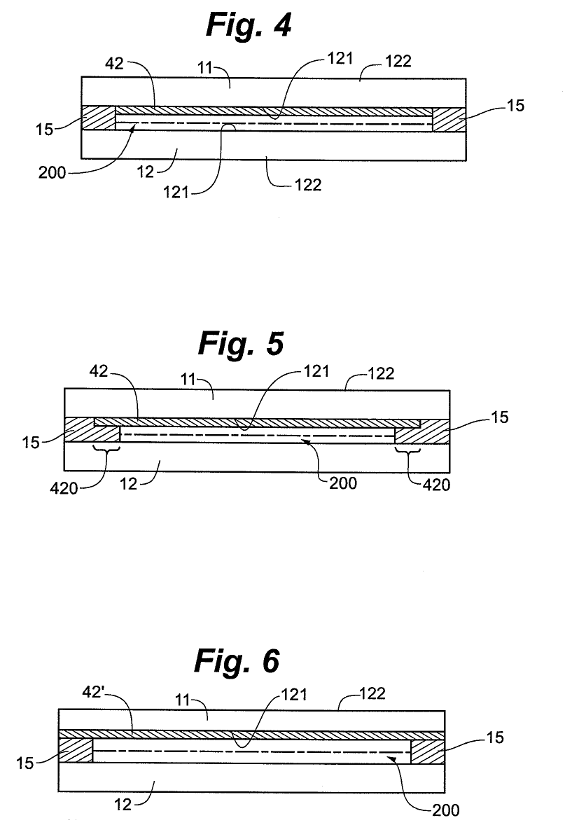

FIG. 1 is a perspective view of a glazing assembly 10, according to some embodiments of the present invention. FIG. 1 illustrates assembly 10 including a first panel, or substrate 11, a second panel, or substrate 12 and a spacer member 15, which is disposed between first substrate 11 and second substrate 12 and which joins substrates 11, 12 together; a first, or inner major surfaces 121 of substrates 11, 12 face inward, or toward one another, being spaced apart from one another by spacer member 15, and second, or outer major surfaces 122 of substrates 11, 12, face outward, or away from one another. First and second surfaces 121, 122 of each substrate 11, 12 may be more clearly seen in the section views of FIGS. 4-6. According to the illustrated embodiment, first substrate 11 is transparent, or light transmitting, for example, formed from glass or a plastic material, such as polycarbonate, and second substrate 12 may be similarly formed, according to some embodiments, but may be opaque according to some alternate embodiments. Although the term “glazing” typically connotes incorporation of a glass panel or substrate, the use of the term is not so limited in the present disclosure, and glazing assemblies of the present invention may incorporate any transparent, or light transmitting substrate, for example, formed from a plastic such as polycarbonate. Further, while the embodiments illustrated in the figures of the present application are depicted with generally rectangular or square shaped substrates, it will be understood that in other embodiments the assembly may be provide with different shapes, e.g. circular or triangular.

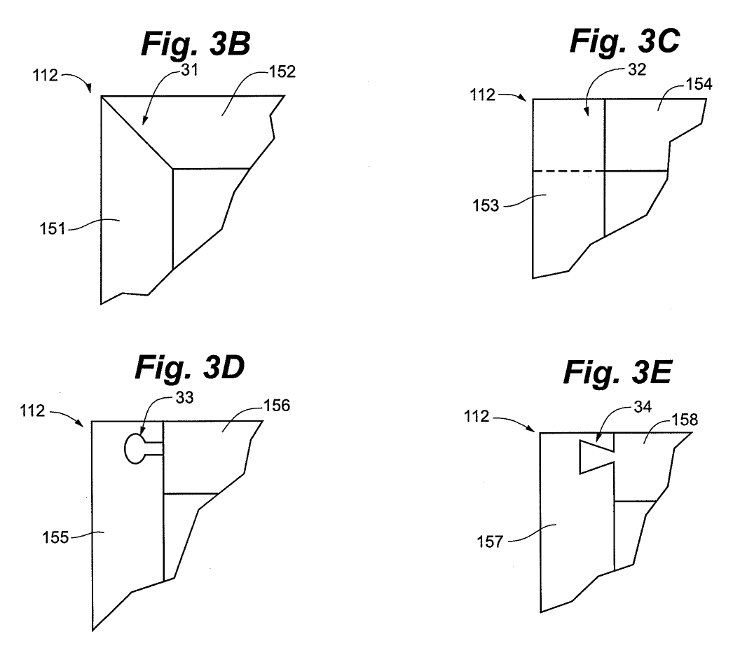

FIG. 2 is a schematic plan view of either of the substrates 11, 12 of assembly 10. FIG. 2 illustrates inner major surface 121 of substrate 11/12 having a central region 108 and a periphery 105, which are delineated from one another by the dashed line. With reference to FIGS. 1 and 2, in conjunction with FIG. 3A, which is a perspective view of assembly 10 having first substrate 11 removed, it may be appreciated that spacer member 15 joins first substrate 11 to second substrate 12 along periphery 105 of each, which are aligned with one another. FIG. 3A illustrates an airspace 200 that extends between inner surfaces 121 of the joined substrates 11, 12. The term airspace, as used herein, is intended to encompass a space that is filled with any type of gas, not only air. FIG. 3A further illustrates spacer member 15 having a thickness t, which, according to preferred embodiments of the present invention, is between approximately 0.01 inch and approximately 0.1 inch, but could be up to 1 inch in alternate embodiments.

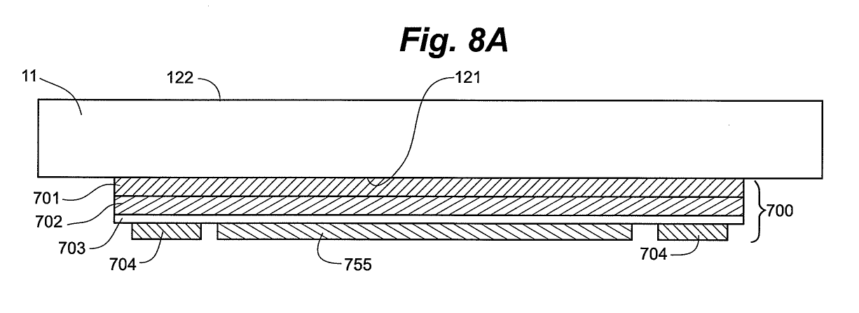

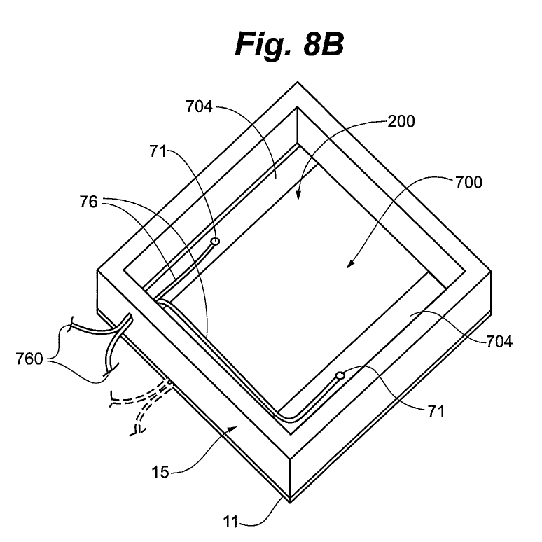

FIG. 3A further illustrates second substrate including optional openings 18, one or both of which may be included in various embodiments. Openings 18, which are shown formed in second substrate 12, may be used to fill airspace 200 with another gas and/or to draw vacuum between joined substrates 11, 12, and/or to dispense a desiccant material into airspace 200. Other secondary manufacturing operations, that are performed within airspace 200, for example, as described below, in conjunction with the embodiment that includes the functional coating of FIG. 8A, may be facilitated by the inclusion of at least one opening 18 in second substrate 12, or opening 19 in spacer member 15.

According to preferred embodiments of the present invention, spacer member 15 is formed from a polymer material having low moisture vapor transmission properties, for example, resulting in a moisture vapor transmission rate (MVTR) therethrough of no greater than approximately 20 g mm/m²/day, in an environment characterized by a relative humidity of approximately 100% and a temperature of approximately 38° C., and as measured per ASTM F 1249. Examples of such suitable materials include, without limitation, ionomers, ethylene methacrylic acid copolymers and polyisobutylenes, the ethylene methacrylic acid copolymers being preferred for their excellent adhesion properties, which are desirable to hold together glazing assemblies such as assembly 10. Some examples of these preferred materials, which are commercially available, are Sentry Glas®Plus, available from DuPont, and PRIMACOR™, available from Dow Chemical.

According to some preferred embodiments, spacer member 15 is pre-formed to have a footprint that matches a shape of peripheries 105. In FIG. 3A spacer member 15 is shown as a four-sided pre-formed member, for example, having been injection molded, or cut out from an extruded or molded sheet of material; the four sides of spacer member 15 extend along first, second, third and fourth straight edges 101, 102, 103, 104 of periphery 105 of each substrate 11, 12 (FIG. 2), and the sides are continuous around corners 112 of the intersecting edges. Of course, alternate shapes of peripheries and the corresponding pre-formed footprints of spacer members are within the scope of the present invention. According to alternate embodiments, each side of spacer member 15 may be independently formed as a strip, for example, via extrusion, molding or cutting from an extruded or molded sheet of material.

FIGS. 3B-E are plan views of alternate corner portions of assembly 10, which illustrate the sides of spacer member 15, which are each independently formed, coming together at corners 112, according to the alternate embodiments. FIG. 3B illustrates a first pre-formed spacer member strip 151 and a second pre-formed spacer member strip 152 coming together at corner 112 in a miter joint 31. FIG. 3C illustrates a first pre-formed spacer member strip 153 and a second pre-formed spacer member strip 154 coming together at corner 112 in a overlap joint 32, wherein strip 153 overlaps strip 154. FIG. 3D illustrates a first pre-formed spacer member strip 155 and a second pre-formed spacer member strip 156 coming together at corner 112 in an interlocking “puzzle piece” joint 33. FIG. 3E illustrates a first pre-formed spacer member strip 157 and a second pre-formed spacer member strip 158 coming together at corner 112 in an interlocking “dove tail” joint 34.

Embodiments of the present invention further include a coating extending over one or both major surfaces 121, 122 of either or both substrates 11/12. According to some preferred embodiments, inner major surface 121 of first substrate 11 bears a coating, for example a low emissivity coating, known to those skilled in the art, or a photovoltaic coating, various embodiments of which are also known to those skilled in the art. The extent of a coating borne by inner surface 121 of first substrate 11, with respect to an extent of spacer member 15, may vary according to various embodiments, examples of which are illustrated in FIGS. 4-6. FIGS. 4-6 are section views through line A-A of FIG. 1, according to various embodiments of the present invention. FIG. 4 illustrates a coating 42 disposed over only central region 108 (FIG. 2) of inner surface 121 of substrate 11, and spacer member 15 extending over only periphery 105 (FIG. 2) of inner surface 121. FIG. 5 illustrates an alternate embodiment wherein spacer member 15 further extends over a portion of central region 108, and over an edge portion 420 of coating 42, which edge portion 420 is located adjacent to periphery 105. FIG. 6 illustrates another alternate embodiment, wherein a coating 42′ is disposed over both central region 108 and periphery 105, of inner surface 121 of substrate 11, so that spacer member 15 extends over a portion of coating 42′.

With further reference to FIGS. 4-6, a dashed line schematically represents an optional desiccant material, which is enclosed within airspace 200 to absorb any moisture that may pass through spacer member 15. The desiccant material, either in sheet or strip form, or granular form, either embedded in a matrix or packaged in a sack, may be ‘free-floating’ in airspace 200, or adhered to one of substrates 11, 12, or otherwise present in airspace 200.

Spacer member 15 may adequately adhere to both the native inner surfaces 121 of substrates 11, 12 and to any of the materials that may form coating 42, 42′, in order to join first and second substrates 11, 12 together for the various embodiments described above. However, according to some preferred embodiments, in which spacer member 15 is formed from an ethylene methacrylic acid copolymer, for example, the Sentry Glas®Plus material, and in which substrates 11, 12 are formed from glass, peripheries 105 are pre-treated with a silane primer, which activates surfaces 121 and thereby enhances the adhesion of spacer member 15 thereto. This enhanced adhesion promotes hydrolytic stability, which is desirable for those applications in which the outer edges of assembly 10 are exposed to the elements, for example, when assembly 10 includes a photovoltaic coating and serves in the capacity of a solar cell.

The use of silane primers to enhance adhesion to glass substrates is known in the art, but there are numerous possible formulations of these primers and the efficacy of a particular formulation depends on various attributes of assembly 10. Therefore, several formulations of silane primers, comprising the silane mixtures described in TABLE 1, below, were evaluated for application to some embodiments of the present invention.

TABLE 1

| | | | Primer |
|---|---|---|---|
| Silane Mixture % | Primer 1 | Primer 2 | 3 |
| Glycidoxypropyl Trimethoxysilane | 65.2% | | |
| (Dow Corning Z-6040) | | | |
| Methacryloxypropyl Trimethoxysilane | | 65.2% | 75.0% |
| (Dow Corning Z-6030) | | | |
| Isobutyl Trimethoxysilane | 21.7% | 21.7% | |
| (Gelest SII 6453.7) | | | |
| Vinyltrimethoxysilane | | | 25.0% |
| (Gelest SIV 9220.0) | | | |
| Bis (triethoxysilyl) ethane | 13.0% | 13.0% | |
| (Gelest SIB 1817.0) | | | |
| Total | 100.0% | 100.0% | 100.0% |

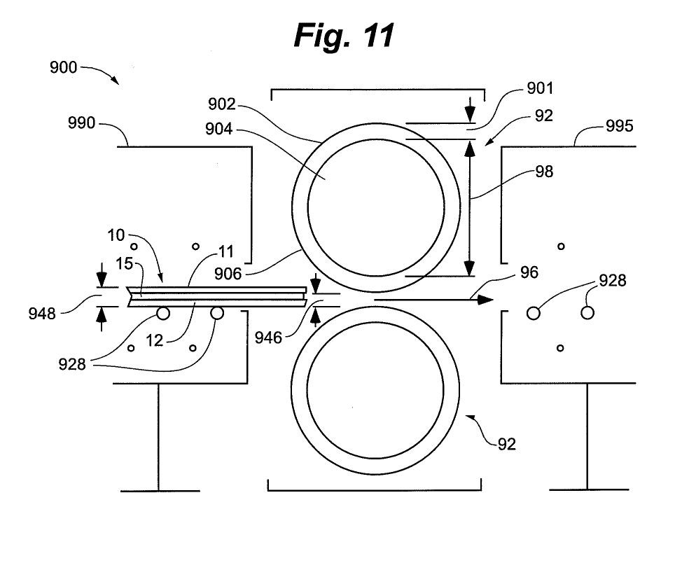

The Primers 1-3 were formulated by combining each of the above silane mixtures (% by weight), in a 2% concentration, by volume, with a corresponding mixture of 95% ethanol and 5% water (by volume), in which the pH had been adjusted to between approximately 4.5 and approximately 5.5 with acetic acid. Each of Primers 1-3 were sprayed onto, and then wiped off from, cleaned surfaces (tin-side) of corresponding glass substrates; each substrate surface had been cleaned with a 50-50 mixture of Isopropyl Alcohol (IPA) and reverse osmosis-filtered (RO) water. Approximately one day after primer application, three sample groups of single-sided laminates were formed, one group for each of Primers 1-3, by adhering an extruded sheet of the Sentry Glas®Plus material (DuPont SGP) to each treated surface of the glass substrates in each group. Each sample was assembled, generally, as follows: an extruded sheet of DuPont SGP was sandwiched between a silane treated side of a first glass substrate and another glass substrate, with a release liner interposed between the other substrate and the SGP; a high temperature tape was used to hold each sample together while the samples were run through a series of ovens and nip rollers, for example, as is described below, in conjunction with FIG. 11; then, the samples were placed in an autoclave in which temperature and pressure were ramped to, and held at, soaked, for about 1 hour, around 280° F. and around 180 psi, respectively; after the soak, the autoclave temperature and pressure were ramped down and the samples removed; and, finally, prior to evaluation, the second glass substrate and liner were removed leaving only the SGP adhered to the treated first glass substrate. A fourth, control, group of samples was also similarly prepared, wherein extruded sheets of DuPont SGP were adhered to non-treated glass substrates, rather than the treated substrates.

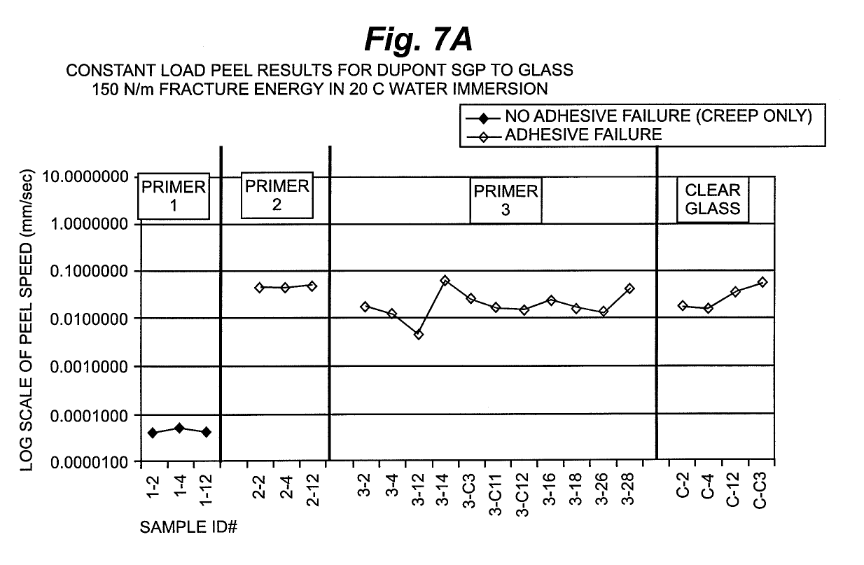

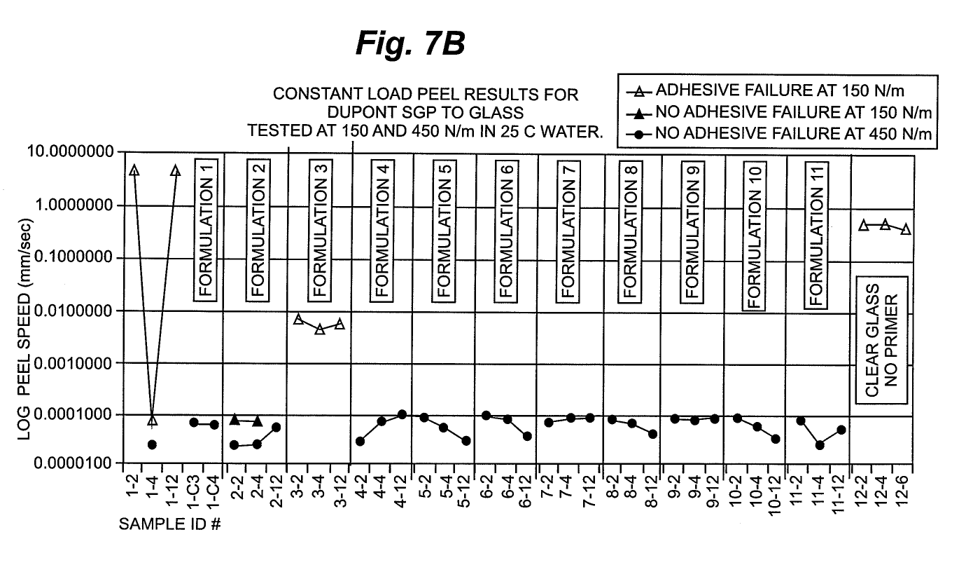

The adhesion of samples from each of the three groups, along with samples from the control group, in which no primer was applied, were peel tested using a fracture mechanics, constant load test method, which is described in: “Measuring and Predicting Sealant Adhesion” PhD Dissertation by Nick E. Shephard (J. P. Wightman), April 1995, Virginia Tech, Center for Adhesive and Sealant Science; and in “A simple device for measuring adhesive failure to sealant joints” by Shephard, N. E. and Wightman, J. P., which is found in: Klosowski, J. M. (Ed.), Science and Technology of Building Seals, Sealants, Glazing, and Waterproofing, Seventh Volume, ASTM STP 1334. American Society for Testing and Materials, Philadelphia, Pa., 1998. The test method provides an indication of adhesion durability by concentrating a load on an adhesive crack tip and measuring the resulting crack growth rate. Testing parameters employed for samples from each of the groups, and the corresponding results are shown in the chart of FIG. 7A. With reference to FIG. 7A, it may be appreciated that Primer 1 significantly enhanced adhesion, while Primers 2 and 3 do not significantly improve adhesion over that measured for samples in the control group. Chemical formulas for each constituent of Primer 1 are as follows:

(3-Glycidoxypropyl) trimethoxysilane: CH₂OCHCH₂OCH₂CH₂CH₂Si(OCH₃)₃;
Isobutyl trimethoxysilane: (CH₃)₂CHCH₂Si(OCH₃)₃; and

### Bis(triethoxysilyl)ethane: (CH₃CH₂O)₃SiCH₂CH₂Si(OCH₂CH₃)₃.

It should be noted that it is anticipated that the “ethoxy form” of each the first two listed constituents of Primer 1: (3-glycidoxypropyl) triethoxysilane (CH₂OCHCH₂OCH₂CH₂CH₂Si(OCH₂CH₃)₃; commercially available as Gelest 5839.0), and Isobutyl triethoxysilane ((CH₃)₂CHCH₂Si(OCH₂CH₃)₃; commercially available as Gelest SII 6453.5), may be substituted for the “methoxy form” of each of these in the above described formulation of Primer 1, without compromising the adhesion enhancement found with Primer 1. The ethoxy form of the third constituent, Bis(triethoxysilyl)ethane, is preferred to the methoxy form thereof, Bis(trimethoxysilyl)ethane ((CH₃O)₃SiCH₂CH₂Si(OCH₃)₃; commercially available as Gelest SIB 1830.0), due to the potential inhalation hazard posed by the methoxy form.

In order to determine a viable range for each silane constituent of Primer 1, a designed experiment was conducted according to the plan outlined in TABLE 2.

TABLE 2

| Silane Mixture % | 1 | 2 | 3 | 4 | 5 | 6 | 7 | 8 | 9 | 10 | 11 |
|---|---|---|---|---|---|---|---|---|---|---|---|
| Glycidoxypropyl | 65.2% | 100% | | | 50% | 50% | 0% | 33.3% | 66% | 17% | 17% |
| Trimethoxysilane | | | | | | | | | | | |
| (Dow Corning Z-6040) | | | | | | | | | | | |
| Isobutyl | 21.7% | | 100% | | 50% | 0% | 50% | 33.3% | 17% | 66% | 17% |
| Trimethoxysilane | | | | | | | | | | | |
| (Gelest SII 6453.7) | | | | | | | | | | | |
| Bis(triethoxysilyl) | 100.0% | | | 100% | 0% | 50% | 50% | 33.3% | 17% | 17% | 66% |
| ethane | | | | | | | | | | | |
| (Gelest SIB 1817.0) | | | | | | | | | | | |
| Total | 100.0% | 100.0% | 100.0% | 100.0% | 100.0% | 100.0% | 100.0% | 100.0% | 100.0% | 100.0% | 100.0% |

Each variation of Primer 1, was formulated by combining each of the TABLE 2. silane mixtures (% by weight), in a 2%, by volume, concentration, with a corresponding mixture of 95% ethanol and 5% water (by volume), in which the pH had been adjusted to between approximately 4.5 and approximately 5.5, with acetic acid. Each of the eleven Primer 1 variations were sprayed onto, and then wiped off from, cleaned surfaces (tin-side) of corresponding glass substrates; each substrate surface had been cleaned with a 50-50 mixture of Isopropyl Alcohol (IPA) and reverse osmosis-filtered (RO) water. Approximately one day after primer application, eleven sample groups of single-sided laminates were formed, one group for each Primer 1 variation, in a manner similar to the sample assembly method described above for the initial evaluation of Primers 1-3.

Peel testing, according to the above-described method, was performed on samples from each of the 11 groups, as well as on control samples. Test parameters and results are presented in the chart in FIG. 7B, wherein the twelfth group of samples 12-2, 12-4 and 12-6, are the control samples. With reference to FIG. 7B, it may be appreciated that those variations of Primer 1, which included either of the silane constituents, Glycidoxypropyl trimethoxysilane or Bis (triethoxysilyl)ethane, alone or in combination with one or both of the other Primer 1 silane constituents, resulted in superior hydrolytically stable adhesion, compared with that of the group 3 Primer 1 variation (samples 3-2, 3-4, 3-12) and no primer.

According to some embodiments of the present invention, coating 42 or 42′ is a ‘thin film’ photovoltaic coating of any type known to those skilled in the art, for example, a thin film CdTe type, which is described below, in conjunction with FIG. 8A, a thin film Cu(InGa)Se₂ (CIGS) type, or an amorphous silicon (a-Si) type. According to preferred embodiments of the present invention, which include the photovoltaic coating, the aforementioned desiccant material, which is enclosed within airspace 200, in combination with the aforementioned relatively low MVTR of spacer member 15, effectively prevents moisture build-up within airspace 200 that can lead to corrosion of certain elements of the photovoltaic coating. With reference to FIG. 8A, according to some preferred embodiments, a sheet-like material 755, to which a plurality of desiccant beads are adhered, is adhered to a photovoltaic coating 700. According to alternate embodiments, desiccant material 755 may be adhered to the opposing substrate 12. It should be noted that some embodiments of the present invention may include a flexible and electrically non-conductive film extending over approximately an entirety of photovoltaic coating 700, such that coating 700 is sandwiched between the film and substrate 11, for example, as is described in commonly assigned and co-pending U.S. patent application, which is entitled: GLAZING ASSEMBLIES THAT INCORPORATE PHOTOVOLTAIC ELEMENTS AND RELATED METHODS OF MANUFACTURE, has the Ser. No. 12/167,826, and is hereby incorporated, by reference, in its entirety.

FIG. 8A is a cross-section of substrate 11 bearing photovoltaic coating 700 over inner surface 121. FIG. 8A illustrates coating 700 including a first layer 701 formed by a transparent conductive oxide (TCO), for example, comprising Tin oxide (SnO₂), which is overlaid with a semiconductor layer 702, for example, comprising two ‘sub-layers’: Cadmium sulfide (CdS; ‘window’ layer; n-type), extending adjacent to first layer 701, and Cadmium Telluride (CdTe; absorbing layer; p-type), overlaying the Cadmium sulfide sub-layer. FIG. 8A further illustrates an electrical contact layer 703, for example, comprising nickel, which extends between the Cadmium Telluride sub-layer of semiconductor layer 702 and a pair of bus bars 704. Bus bars 704 may each be formed from a copper tape, for example, approximately 0.003-0.007 inch thick, which are adhered to contact layer 703, for example, by conductive acrylic adhesive. Bus bars 704 preferably extend approximately parallel to one another along opposing edge portions of coating 700 and electrical lead wires 76 (FIG. 8B) are coupled bus bars 704 for powering of assembly 10 as a solar cell. Lead wires 76 may be routed out from between substrates 11, 12 through one of openings 18 (FIG. 3A), or out through spacer member 15, for example, as is illustrated in FIG. 8B.

FIG. 8B is a perspective view of a portion of a glazing assembly, for example, similar to assembly 10 of FIG. 1, wherein spacer member 15 is pre-formed to include lead wires 76 extending therethrough, for example, via insert injection molding. FIG. 8B illustrates each of lead wires 76 including an inner terminal end 71 coupled to the corresponding bus bar 704 of coating 700, within airspace 200, and each of lead wires 76 including an outer terminal end 760, which are accessible outside of airspace 200. According to the illustrated embodiment, inner terminal ends 71 are be coupled to bus bars 704 prior to affixing first and second substrates 11, 12 to spacer member 15, and then outer terminal ends 760 may be coupled to a power source upon installation of the completed glazing assembly. Thus, opening(s) 18 (FIG. 3A) are not necessary for embodiments of glazing assemblies that include the wire routing illustrated in FIG. 8B, nor for yet another wire routing embodiment in which the lead wires are passed out from airspace 200 between spacer member 15 and first substrate 11, for example, as illustrated with dashed lines in FIG. 8B. According to additional alternate embodiments, spacer member 15 includes a pre-formed opening 19 (FIG. 3A) through which lead wires may be routed; and, according to yet further alternate embodiments, lead wires may be routed by piercing through spacer member 15, or by extending alongside spacer member 15, between spacer member 15 and substrate 11, as mentioned above.

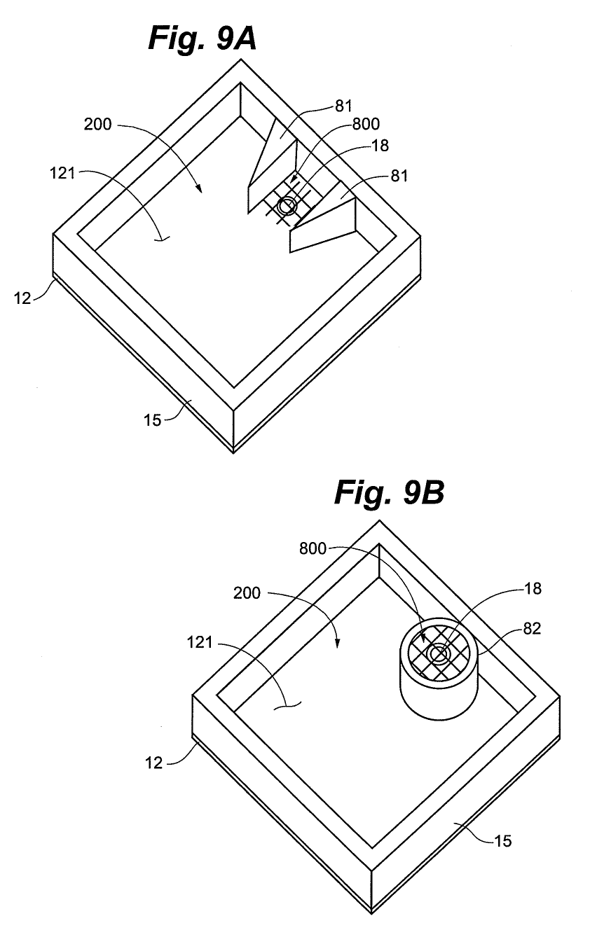

FIGS. 9A-B are perspective views of a portion of a glazing assembly, for example, similar to assembly 10, shown in FIG. 1, wherein first substrate 11 is removed for clarity in illustration. FIGS. 9A-B present some alternate embodiments of support members that can provide additional stability to the spacing between substrates 11, 12, which is established by spacer member 15; the support members can also control other features of the assembly, as is further described below.

FIG. 9A illustrates the assembly including a pair of support members 81, each of which, preferably, has a thickness, like spacer member 15, to span airspace 200 between first substrate 11 and second substrate 12. FIG. 9A further illustrates support members 81 surrounding a portion of a perimeter of opening 18. FIG. 9B illustrates the assembly including a support member 82, which also has a thickness, like spacer member 15 and support members 81 of FIG. 9A, to span airspace 200, but which completely surrounds the perimeter of opening 18. According to the illustrated embodiments, after opening 18 has provided access to airspace, for example, for performing any of the aforementioned secondary operations, a potting material 800 may be applied to seal off opening 18, in which case, either of support members 81, 82 can provide a barrier to control the flow of potting material 800, and thereby limit an extent of material 800 over inner surface 121 of each of substrates 11, 12. As previously described, opening 18 may further provide a passageway for routing lead wires that are coupled to photovoltaic coating 700 (FIG. 8A-B); according to these embodiments, potting material 800 is applied around the lead wires within opening 18. According to some preferred embodiments, support members 81, 82 are formed from a low MVTR material, for example, selected from the same group previously described for spacer member 15. With reference to FIG. 9B, it may be appreciated that support member 82, being formed of the preferred material, can function to further seal airspace 200 from moisture ingress through opening 18. Although support members 81, 82 are shown being formed as separate members from spacer, according to alternate embodiments, support members 81, 82 are integrally pre-formed with spacer member 15, for example, via injection molding.

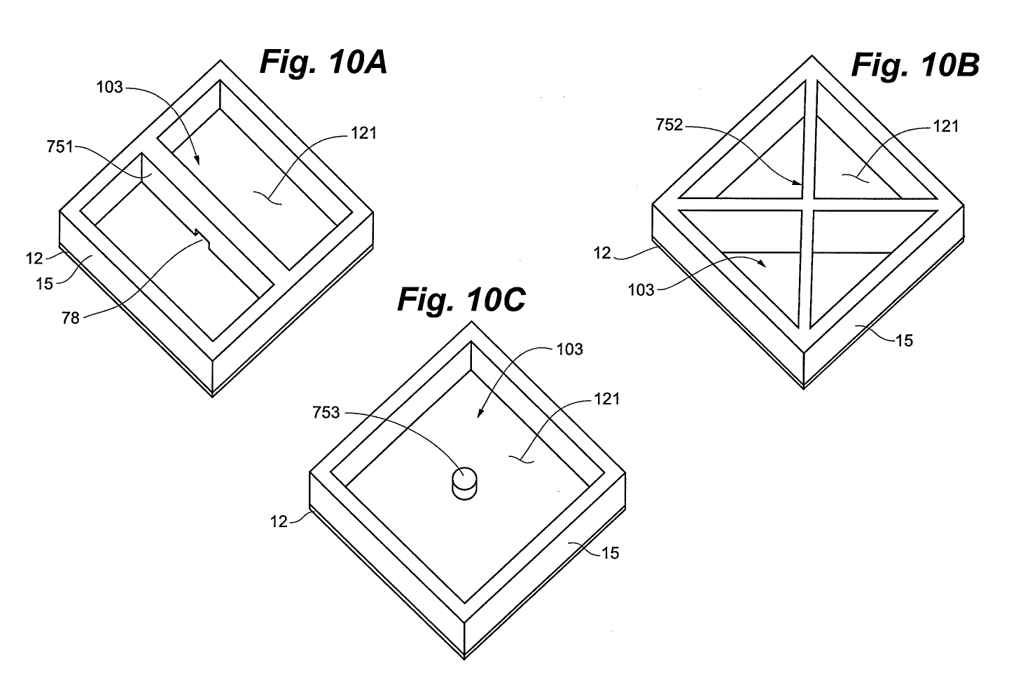

FIGS. 10A-C present some additional alternate embodiments of support members, which provide additional stability to the spacing between substrates 11, 12. FIGS. 10A-C illustrate support members 751, 752 and 753, respectively, each, preferably, having a thickness similar to that of spacer member 15, to span airspace. FIG. 10A shows support member 751 extending from one side to another of spacer member 15; FIG. 10B shows support member 752 extending diagonally between opposing corners of spacer member 15; and FIG. 10C shows support member 753 being centrally located and independent of spacer member 15. Any of support members 751, 752, 753 may be incorporated in assembly 10, in combination with either of support members 81, 82, which were previously described in conjunction with FIGS. 9A-B. Each of support members 751, 752, 753 may be formed from the same material that forms spacer member 15. According to some embodiments, either of support members 751 and 752 may be integrally formed with spacer member 15, for example, via injection molding, or may be formed from independent strips of material. For those embodiments in which support members divide airspace 200 into sub-compartments, for example, member 751 or member 752, an opening, such as opening 78 shown in FIG. 10A, is preferably formed through a portion of the support member to provide for fluid communication between the sub-compartments, for example, so that desiccant material need not be separately placed in each sub-compartment.

Some methods for making glazing assembly 10, as generally shown in FIG. 1, and according to any of the alternative embodiments, which are described in conjunction with FIGS. 1-10C, will now be described. Initially, a pair of panels, or substrates, for example substrates 11, 12, are formed according to methods well known in the art. Formation of at least one of the substrates includes a step of coating a major surface of the substrate. According to some preferred methods, the major surface of one of the substrates, which will face a major surface of the other substrate in the glazing assembly, for example, first, or inner surface 121 of first substrate 11, is coated with either a low emissivity coating or a photovoltaic coating, according to methods known to those skilled in the art.

The initial substrate formation may further include a step of forming at least one opening through one or both of the substrates, but preferably, just through the substrate which does not include the coating. According to some preferred methods, initial substrate formation further includes a step in which a desiccant material is adhered to that surface, of one or both of the substrates, which will be the inner surface of the assembly, for example, as previously described in conjunction with FIG. 8A. When the coating is a photovoltaic coating, for example, coating 700 (FIG. 8A), lead wires, for example, wires 76 (FIG. 8B), are preferably attached at this time too.

According to preferred methods, either prior to, during, or following substrate formation, a spacer member, for example, spacer member 15, is formed, either via extrusion or molding, from a low MVTR material. The spacer member may be cut from a pre-extruded sheet of material, and the left over portions of the sheet recycled, or, preferably, the spacer member is injection molded. The spacer member is then sandwiched between the facing surfaces of the pair of substrates, along aligned peripheries thereof, while maintaining an airspace between the facing surfaces. When the spacer member is sandwiched between the substrates, one or more support members, for example, any of support members 81, 82, 751, 752, 753, having approximately the same thickness as the spacer member, may also be sandwiched between the substrates. Following the sandwiching, according to some preferred methods of the present invention, heat and pressure are applied to adhere, or affix the spacer member, and the support member(s), if included, to the facing surfaces of the pair of substrates in order to form a coherent assembly, for example, assembly 10, which still includes an airspace, such as airspace 200.

According to some methods, a primer is formulated, preferably to include one or more silane constituents, and then applied, for example, according to the method previously described, to the peripheries of the major surfaces to which the spacer member is adhered, in a step that precedes that in which spacer member is sandwiched. It should be noted that the primer may be applied to more than just the peripheries of the surfaces, for example, to central regions as well, so that process controls need not be employed to limit the application of the primer to only the peripheries, although some methods of the invention may do so. According to some preferred embodiments, the primer includes one or more of the silane constituents, presented above, in any of the mixtures, described above, for example, for Primer 1, or any of the eleven variations thereof.

Turning now to FIG. 11, a portion of an exemplary production line 900 for applying the aforementioned heat and pressure will now be described. Portions of FIG. 11 have been borrowed from commonly assigned U.S. Pat. No. 7,117,914, which describes such a production line in detail, and those portions of the '914 patent that describe the production line, are hereby incorporated by reference. FIG. 11 schematically illustrates assembly 10 being conveyed, on rollers 928, along a path 96 that travels through at least two ovens 990, 995; a pair of confronting press members 92, which are embodied as nip rollers, are located along path 96 between ovens 990, 995. According to the illustrated embodiment, oven 990, which is the first oven of production line 900, heats assembly 10, as it is conveyed therethrough, to a temperature, preferably between approximately 200° F. and approximately 300° F.; heated assembly 10 is then delivered between confronting press members 92, which apply a pressure to press substrates 11, 12 toward one another, and then assembly 10 is conveyed through oven 995, which re-heats assembly 10 to a temperature, preferably between approximately 200° F. and approximately 300° F. Although not shown in FIG. 11, a preferred production line further includes another pair of press members 92, which are located downstream of oven 955 to provide a second application of pressure to assembly 10.

FIG. 11 further illustrates each member 92 including a rigid cylinder 904 that has a diameter 98; cylinder 904 is overlaid with a relatively soft cover 906 that has a thickness 901. An outer surface 902 of cover 906 is preferably textured in a pattern similar to that of an automobile tire tread; exemplary materials and texture patterns for cover 906 are described in detail in the aforementioned '914 patent. Press members 92 are shown spaced apart from one another in order to form a gap 946 through which assembly 10 travels as assembly 10 is conveyed along path 96; gap 946 is preferably smaller than an overall thickness 948 of assembly 10 so that confronting press members 92 can apply the pressure necessary to adhere/affix substrates 11, 12 to spacer member 15. Gap 946 may be varied, for a given thickness of assembly 10, according to a durometer of cover 906, the softer the cover, the smaller the gap. The second set of confronting press members 92, not shown, but previously described as being downstream of oven 955, are preferably spaced apart by a gap that is smaller than gap 946.

The preferred temperature ranges, which are indicated above, are applicable to preferred low MVTR materials, in particular, the Sentry Glas®Plus material. For this material and the preferred temperature ranges, a rate of transport for glazing assemblies, like assembly 10, through production line 900 may be between approximately 10 feet/minute and approximately 20 feet/minute. It should be noted that, although production line 900 has been found to provide good operating efficiency for relatively large volume production of assemblies, such as assembly 10, the scope of the present invention is not limited by any particular production process for adhering/affixing substrates 11, 12 to spacer member 15. Other suitable processes, which are known in the art, include vacuum lamination processes, for example, either those employing clam shell-type fixturing or an autoclave.

According to those embodiments that include one or more openings, for example, openings 18, 19 (FIG. 3A), after substrates 11, 12 are adhered to spacer member 15, the opening(s) may be used to perform secondary operations related to an airspace, for example, airspace 200. Examples of these secondary operations, include, without limitation, dispensing a desiccate material into airspace 200, in addition to, or as an alternative to, adhering the desiccant, as previously described, filling airspace 200 with a gas, and pulling vacuum in airspace 200. According to those embodiments that include a photovoltaic coating, for example, those described in conjunction with FIGS. 7A-B, lead wires, which are coupled to the coating, may be routed out through the opening, either prior to the adhering/affixing process, for example, in conjunction with the sandwiching step, or following the adhering/affixing process. However, according to the aforementioned alternate embodiments, the coupled lead wires are routed out through spacer member 15, for example, as previously described in conjunction with FIG. 8B. A diameter of opening(s) 18 may be between approximately ¼ inch and approximately 1 inch in order to accommodate these secondary operations. For those embodiments including opening(s) 18, and/or opening 19, the opening(s), are sealed off with a potting material after the secondary operations are completed. If substrate 12 bears a photovoltaic coating, along an inner, or first surface 121 thereof, and lead wires extend through the one or more openings, then the potting material is applied around the lead wires, to seal off the opening. Examples of suitable potting materials include, without limitation, polyurethane, epoxy, polyisobutylene, and any low MVTR material; according to some embodiments, the same material which forms spacer member 15 may be used for the potting material.

In the foregoing detailed description, the invention has been described with reference to specific embodiments. However, it may be appreciated that various modifications and changes can be made without departing from the scope of the invention as set forth in the appended claims.

We claim:

1. A glazing assembly comprising:
a first substrate including an inner major surface, the inner major surface including a central region and a periphery;
a functional coating extending over, and being adhered to, the central region of the inner surface of the first substrate;
a second substrate opposing the first substrate and including an inner major surface, the inner major surface including a central region and a periphery, the central region of the inner major surface of the second substrate facing the central region of the inner major surface of the first substrate, and the periphery of the first substrate being aligned with the periphery of the second substrate; and
a spacer member being formed of a material having properties that result in a moisture vapor transmission rate therethrough of no greater than approximately 20 g mm/m²/day, in an environment characterized by a relative humidity of approximately 100% and a temperature of approximately 38° C., and as measured per ASTM F 1249, the spacer member being disposed between the first and second substrates and being directly adhered to the periphery of each of the first and second substrates, such that the spacer member encloses an airspace that extends between the central regions of the inner surfaces of the first and second substrates, the spacer member being pre-formed to have a footprint that matches a shape of the periphery of each of the first and second substrates.

2. The assembly of claim 1, wherein the functional coating is disposed over both the central region and the periphery of the inner surface of the first substrate.

3. The assembly of claim 1, wherein the functional coating is disposed over only the central region of the inner surface of the first substrate.

4. The assembly of claim 1, wherein the spacer member extends over an edge portion of the functional coating, the edge portion being located adjacent to the periphery of the inner surface of the first substrate.

5. The assembly of claim 1, further comprising a support member disposed between the central regions of the first and second substrates, the support member being adhered to at least the central region of the second substrate.

6. The assembly of claim 5, wherein the support member is integrally formed with the spacer member.

7. The assembly of claim 5, wherein the support member is formed of a material having properties that result in a moisture vapor transmission rate therethrough of no greater than approximately 20 g mm/m²/day, in an environment characterized by a relative humidity of approximately 100% and a temperature of approximately 38° C., and as measured per ASTM F 1249,

8. The assembly of claim 1, further comprising a desiccant material disposed within the airspace.

9. The assembly of claim 8, wherein the desiccant material is adhered to the functional coating.

10. The assembly of claim 1, wherein the second substrate includes an opening extending therethrough, the opening being located in the central region thereof.

11. The assembly of claim 10, further comprising a support member disposed between the central region of the first and second substrates and surrounding at least a portion of a perimeter of the opening.

12. The assembly of claim 11, wherein the support member is integrally formed with the spacer member.

13. The assembly of claim 11, wherein the support member is formed of a material having properties that result in a moisture vapor transmission rate therethrough of no greater than approximately 20 g mm/m²/day, in an environment characterized by a relative humidity of approximately 100% and a temperature of approximately 38° C., and as measured per ASTM F 1249,

14. The assembly of claim 1, wherein the material from which the spacer member is formed is selected from the group consisting of: ionomers, ethylene methacrylic acid copolymers and polyisobutylenes.

15. The assembly of claim 1, wherein the functional coating comprises a low emissivity coating.

16. The assembly of claim 1, wherein the functional coating comprises a photovoltaic coating.

17. The assembly of claim 1, wherein the periphery of each of the first and second substrates includes a primed surface to which the spacer member is directly adhered, the primed surface including a silane primer.

18. The assembly of claim 17, wherein the silane primer comprises a mixture of at least two silane constituents, the at least two silane constituents being selected from the group consisting of: 3-glycidoxypropyl trimethoxysilane, 3-glycidoxypropyl triethoxysilane, Isobutyl trimethoxysilane, Isobutyl triethoxysilane, and Bis (triethoxysilyl) ethane.

19. The assembly of claim 17, wherein the silane primer comprises a single silane constituent, the single silane constituent being selected from the group consisting of: 3-glycidoxypropyl trimethoxysilane, 3-glycidoxypropyl triethoxysilane, and Bis (triethoxysilyl)ethane.

20. A glazing assembly comprising:
a first substrate including an inner major surface, the inner major surface including a central region and a periphery;
a photovoltaic coating extending over, and being adhered to, the central region of the inner surface of the first substrate;
a second substrate opposing the first substrate and including an opening, extending therethrough, and an inner major surface, the inner major surface including a central region and a periphery, the central region of the inner major surface of the second substrate facing the central region of the inner major surface of the first substrate, the periphery of the first substrate being aligned with the periphery of the second substrate, and the opening being located in the central region of the second substrate;
a spacer member being disposed between the first and second substrates and being directly adhered to the periphery of each of the first and second substrates, such that the spacer member encloses an airspace that extends between the central regions of the inner surfaces of the first and second substrates; and
a support member disposed between the central regions of the first and second substrates;
wherein the support member has a thickness to span the airspace between the inner surfaces of the first and second substrates; and
the support member surrounds at least a portion of a perimeter of the opening of the second substrate.

21. The assembly of claim 20, wherein at least one of the spacer member and the support member is formed of a material having properties that result in a moisture vapor transmission rate therethrough of no greater than approximately 20 g mm/m²/day, in an environment characterized by a relative humidity of approximately 100% and a temperature of approximately 38° C., and as measured per ASTM F 1249.

22. The assembly of claim 20, wherein at least one of the spacer member and the support member is formed of a material selected from the group consisting of: ionomers, ethylene methacrylic acid copolymers and polyisobutylenes.

23. The assembly of claim 20, wherein the support member is integrally formed with the spacer member.

24. The assembly of claim 20, wherein the spacer member is pre-formed to have a footprint that matches a shape of the periphery of each of the first and second substrates.

25. The assembly of claim 20, wherein the spacer member comprises at least one pre-formed strip.

26. The assembly of claim 20, wherein:
the periphery of each of the first and second substrates comprises a corner, a first straight edge and second straight edge, the first and second edges coming together at the corner and extending approximately orthogonal to one another; and
the spacer member comprises a first pre-formed strip extending along the first straight edge and a second pre-formed strip extending along the second straight edge, the first and second pre-formed strips coming together at the corner.

27. The assembly of claim 26, wherein the first and second pre-formed strips come together in one of: a miter joint, an overlap joint, and an interlocking joint.

28. The assembly of claim 20, wherein the photovoltaic coating is disposed over both the central region and the periphery of the inner surface of the first substrate.

29. The assembly of claim 20, wherein the photovoltaic coating is disposed over only the central region of the inner surface of the first substrate.

30. The assembly of claim 20, wherein the spacer member extends over an edge portion of the photovoltaic coating, the edge portion being located adjacent to the periphery of the inner surface of the first substrate.

31. The assembly of claim 20, further comprising a desiccant material disposed within the airspace.

32. The assembly of claim 31, wherein the desiccant material is adhered to the photovoltaic coating.

33. The assembly of claim 20, wherein:
the periphery of each of the first and second substrates includes a primed surface to which the spacer member is directly adhered, the primed surface including a silane primer; and
the material from which spacer member is formed is an ethylene methacrylic acid copolymer.

34. The assembly of claim 33, wherein the silane primer comprises a mixture of at least two silane constituents, the at least two silane constituents being selected from the group consisting of: 3-glycidoxypropyl trimethoxysilane, 3-glycidoxypropyl triethoxysilane, Isobutyl trimethoxysilane, Isobutyl triethoxysilane, and Bis (triethoxysilyl) ethane.

35. The assembly of claim 33, wherein the silane primer comprises a single silane constituent, the single silane constituent being selected from the group consisting of: 3-glycidoxypropyl trimethoxysilane, 3-glycidoxypropyl triethoxysilane, and Bis (triethoxysilyl)ethane.

36. A method for making a glazing assembly, the method comprising:
forming a spacer member to have a footprint that matches a shape of both a periphery of a first major surface of a first substrate and a periphery of a first major surface of a second substrate, the spacer member being formed from a material having properties that result in a moisture vapor transmission rate therethrough of no greater than approximately 20 g mm/m²/day, in an environment characterized by a relative humidity of approximately 100% and a temperature of approximately 38° C., and as measured per ASTM F 1249, the periphery of the first substrate surrounding a central region of the first major surface of the first substrate, and the periphery of the second substrate surrounding a central region of the first major surface of the second substrate;
sandwiching the spacer member between the periphery of the first substrate and the periphery of the second substrate; and
adhering the sandwiched spacer member directly to the periphery of each of the first and second substrates, such that an airspace, which extends between the central regions of the first and second substrates, is maintained and enclosed by the spacer member;
wherein a functional coating extends over and is adhered to the central region of one of the first and second substrates.

37. The method of claim 36, wherein adhering comprises applying pressure to second major surfaces of the first and second substrates, after heating the first and second substrates to a temperature between approximately 200° F. and approximately 300° F., each second major surface being opposite the corresponding first major surface.

38. The method of claim 36, wherein the adhering is carried out by conveying the first and second substrates and the sandwiched spacer member through a first of oven, and then between a first pair of confronting pressing members, and then through a second oven, and then between a second pair of confronting press members.

39. The method of claim 36, further comprising adhering a desiccant to the central region of one of the first and second substrates, prior to sandwiching the spacer member.

40. The method of claim 36, wherein the functional coating comprises a photovoltaic coating and further comprising attaching a lead wire to a bus bar of the photovoltaic coating.

41. The method of claim 40, wherein forming the spacer member comprises insert injection molding to include the lead wire extending therethrough.

42. The method of claim 40, further comprising:
forming an opening through one of the first and second substrates, the opening being located in the central region of the one of the first and second substrates; and
routing the lead wire through the opening.

43. The method of claim 42, further comprising:
forming a support member; and
sandwiching the support member between the central region of the first substrate and the central region of the second substrate such that the support member surrounds at least a portion of a perimeter of the opening.

44. The method of claim 43, wherein the support member is formed from a material having properties that result in a moisture vapor transmission rate therethrough of no greater than approximately 20 g mm/m²/day, in an environment characterized by a relative humidity of approximately 100% and a temperature of approximately 38° C., and as measured per ASTM F 1249.

45. The method of claim 36, further comprising:
forming a support member; and
sandwiching the support member between the central region of the first substrate and the central region of the second substrate.

46. The method of claim 45, wherein the support member is formed from a material having properties that result in a moisture vapor transmission rate therethrough of no greater than approximately 20 g mm/m²/day, in an environment characterized by a relative humidity of approximately 100% and a temperature of approximately 38° C., and as measured per ASTM F 1249.

47. The method of claim 45, wherein forming the support member occurs simultaneously with forming the spacer member, the support member being integral with the spacer member.

48. The method of claim 36, further comprising applying a silane primer to the periphery of each of the first and second substrates, prior to sandwiching the spacer member.

49. The method of claim 48, further comprising:
forming a mixture of at least two silane constituents, the at least two silane constituents being selected from the group consisting of: 3-glycidoxypropyl trimethoxysilane, 3-glycidoxypropyl triethoxysilane, Isobutyl trimethoxysilane, Isobutyl triethoxysilane, and Bis (triethoxysilyl)ethane; and
forming the silane primer by combining the mixture with an ethanol-water-acetic acid solution for a 2%, by volume, concentration of the mixture in the solution.

50. The method of claim 48, further comprising forming the silane primer by combining a single silane constituent with an ethanol-water-acetic acid solution for a 2%, by volume, concentration of the single silane constituent in the solution, the single silane constituent being selected from the group consisting of: 3-glycidoxypropyl trimethoxysilane, 3-glycidoxypropyl triethoxysilane, and Bis (triethoxysilyl)ethane.

51. A method for making a glazing assembly, the method comprising:
applying a silane primer to a periphery of a first major surface of a first substrate and to a periphery of a first major surface of a second substrate, the periphery of the first substrate surrounding a central region of a first major surface of the first substrate, and the periphery of the second substrate surrounding a central region of a first major surface of the second substrate;
sandwiching a spacer member between the periphery of the first substrate and the periphery of the second substrate, after applying the primer, the spacer member being formed from an ethylene methacrylic acid copolymer; and
adhering the sandwiched spacer member directly to the periphery of each of the first and second substrates, such that an airspace, which extends between the central regions of the first and second substrates, is maintained and enclosed by the spacer member.

52. The method of claim 51, further comprising:
forming a mixture of at least two silane constituents, the at least two silane constituents being selected from the group consisting of: 3-glycidoxypropyl trimethoxysilane, 3-glycidoxypropyl triethoxysilane, Isobutyl trimethoxysilane, Isobutyl triethoxysilane, and Bis (triethoxysilyl)ethane; and
forming the silane primer by combining the mixture with an ethanol-water-acetic acid solution for a 2%, by volume, concentration of the mixture in the solution.

53. The method of claim 51, further comprising forming the silane primer by combining a single silane constituent with an ethanol-water-acetic acid solution for a 2%, by volume, concentration of the single silane constituent in the solution, the single silane constituent being selected from the group consisting of: 3-glycidoxypropyl trimethoxysilane, 3-glycidoxypropyl triethoxysilane, and Bis (triethoxysilyl)ethane.

54. The method of claim 51, wherein adhering comprises applying pressure to second major surfaces of the first and second substrates, after heating the first and second substrates to a temperature between approximately 200° F. and approximately 300° F., each second major surface being opposite the corresponding first major surface.

55. The method of claim 51, wherein the adhering is carried out by conveying the first and second substrates and the sandwiched spacer member through a first of oven, and then between a first pair of confronting pressing members, and then through a second oven, and then between a second pair of confronting press members.

56. The method of claim 51, further comprising adhering a desiccant to the central region of one of the first and second substrates, prior to sandwiching the spacer member.

57. The method of claim 51, wherein:
a photovoltaic coating extends over and is adhered to the central region of one of the first and second substrates; and
further comprising attaching a lead wire to a bus bar of the photovoltaic coating.

58. The method of claim 57, wherein forming the spacer member comprises insert injection molding to include the lead wire extending therethrough.

59. The method of claim 57, further comprising:
forming an opening through one of the first and second substrates, the opening being located in the central region of the one of the first and second substrates; and
routing the lead wire through the opening.

60. A glazing assembly comprising:
a first substrate including an inner major surface, the inner major surface including a central region and a periphery;
a functional coating extending over, and being adhered to, the central region of the inner surface of the first substrate;
a second substrate opposing the first substrate and including an inner major surface, the inner major surface including a central region and a periphery, the central region of the inner major surface of the second substrate facing the central region of the inner major surface of the first substrate, the periphery of the first substrate being aligned with the periphery of the second substrate, and each periphery including a corner, a first straight edge and a second straight edge, the first and second edges coming together at the corner and extending approximately orthogonal to one another; and
a spacer member disposed between the first and second substrates and being directly adhered to the periphery of each of the first and second substrates, such that the spacer member encloses an airspace that extends between the central regions of the inner surfaces of the first and second substrates, the spacer member being formed of an ethylene methacrylic acid copolymer and including a first pre-formed strip, extending along the first straight edge of each periphery, and a second pre-formed strip, extending along the second straight edge of each periphery;
wherein the first and second strips come together at the corner of each periphery in one of: a miter joint, an overlap joint, and an interlocking joint.

61. The assembly of claim 60, wherein the functional coating comprises a low emissivity coating.

62. The assembly of claim 60, wherein the functional coating comprises a photovoltaic coating.

63. The assembly of claim 60, wherein the periphery of each of the first and second substrates includes a primed surface to which the spacer member is directly adhered, the primed surface including a silane primer.

64. The assembly of claim 63, wherein the silane primer comprises a mixture of at least two silane constituents, the at least two silane constituents being selected from the group consisting of: 3-glycidoxypropyl trimethoxysilane, 3-glycidoxypropyl triethoxysilane, Isobutyl trimethoxysilane, Isobutyl triethoxysilane, and Bis (triethoxysilyl) ethane.

65. The assembly of claim 63, wherein the silane primer comprises a single silane constituent, the single silane constituent being selected from the group consisting of: 3-glycidoxypropyl trimethoxysilane, 3-glycidoxypropyl triethoxysilane, and Bis (triethoxysilyl)ethane.
